(19) United States
(12) Patent Application Publication
(10) Pub. No.: US 2003/0183931 A1
(43) Pub. Date: Oct. 2, 2003

(54) Semiconductor apparatus, fixture for measuring characteristics therefor, and semiconductor device characteristics measuring apparatus

(75) Inventor: Shinobu Isobe, Tateyama-shi (JP)

Correspondence Address: COHEN, PONTANI, LIEBERMAN & PAVANE, 551 FIFTH AVENUE, SUITE 1210, NEW YORK, NY, 10176, US

(73) Assignee: UMC Japan, Tateyama-shi (JP)

(21) Appl. No.: 10/395,689

(22) Filed: Mar. 24, 2003

(30) Foreign Application Priority Data
Mar. 26, 2002 (JP) P2002-086862

(51) Int. Cl. H01L 23/48

(52) U.S. Cl. 257/734

(57) ABSTRACT

A surface of a silicon wafer having bump electrodes is divided in a matrix manner by scribe lines (2 and 3). The divided areas are silicon chips (4). A plurality of bumps 5 are formed on predetermined positions on the silicon chips (4). The bumps (5) are electrically conductive wear-resistant members so as to withstand repeated use. By doing this, it is possible to provide a semiconductor device which can realize a mounting operation for a semiconductor substrate of small size with high density at low cost and to measure electrical characteristics for semiconductor wafers and semiconductor chips efficiently in a manufacturing process or after a mounting operation.

### BACKGROUND OF THE INVENTION

1. Field of the Invention

The present invention relates to a semiconductor device which can realize a mounting operation for a semiconductor substrate of small size with high density at low cost and can measure electrical characteristics for a semiconductor wafer and semiconductor chip efficiently in a manufacturing process or after the mounting operation. The present invention also relates to a fixture for measuring characteristics for the semiconductor device, and a semiconductor device characteristics measuring apparatus therewith.

2. Description of Related Art

Conventionally, for a manufacturing method, as a general method for a semiconductor device such as an IC (Integrated Circuit), an LSI (Large Scale Integration), and VLSI (Very Large Scale Integration), it is known that a predetermined circuit pattern is exposed on a silicon wafer, this silicon wafer is cut into chip units so as to form a silicon chip in which a predetermined circuit network is formed, the silicon chip is fixed on a lead frame, and pad electrodes on the silicon chip and terminals on the lead frame are electrically connected by gold wire by using a wire bonding apparatus so as to further perform a resin molding operation on the silicon chip. Conventionally, a semiconductor device as a final product has been obtained in above explained manner.

To a final product of this semiconductor device, various tests such as a Burn-in test (acceleration test under a predetermined temperature) and a function test (a test for confirming the electrical characteristics) are performed.

In these tests, a package socket is used so as to fix and electrically connect the devices as final products. In a measuring operation, the above-mentioned devices are inserted into the package sockets, and at the same time, the terminals of the device are contacted to electrodes which are disposed on the package sockets, and furthermore, the package sockets are fixed on a circuit on the printed board, and the terminals on the device and the circuit on the printed board are connected electrically. After that, various tests such as Burn-in test and function test are performed on the device.

Recently, along with a large-scale integration of semiconductor chips, the numbers of semiconductor chips and lead frames have increased. Therefore, the number of terminals in the package socket has also increases; thus, the size of the semiconductor device inevitably becomes large and its structure is more complicated.

On the other hand, downsizing and higher specification are required for various electric apparatuses on regular bases. Therefore, for example, the size of the package in the device is required to be approximately the same size as the size of the chip in a device such as a chip-size-package. Also, it is required that more dense mounting operation be performed to a board for mounting a device.

However, there was a limit to downsizing in the package for containing the chip and mounting operation in dense condition. Thus, it was necessary to propose a new device so as to realize a downsizing and high density mounting of the device.

Furthermore, in addition to the downsizing and high density mounting for the device, it is desired that further cost reduction for the product be realized.

### SUMMARY OF THE INVENTION

The present invention was made in consideration of the problems above. An object of the present invention is to provide a semiconductor device which can realize a mounting operation for a semiconductor substrate of small size with high density at low cost and measure electrical characteristics for a semiconductor wafer and semiconductor chip efficiently in a manufacturing process or after the mounting operation. Other object of the present invention is to provide a fixture for measuring characteristics for the semiconductor device, and a semiconductor device characteristics measuring apparatus therewith. In order to solve the problems above, the present invention provides a semiconductor device, a fixture for measuring characteristics for the semiconductor device, and a semiconductor device characteristics measuring apparatus therewith as follows.

That is, a semiconductor device according to a first aspect of the present invention has a plurality of bumps on a main surface of a semiconductor substrate.

In a semiconductor device according to a second aspect of the present invention, the bumps are electrically conductive wear-resistant members.

In a semiconductor device according to a third aspect of the present invention, the bumps are approximately round or polygonal. According to a fourth aspect of the present invention, a fixture for measuring electrical characteristics of the semiconductor device has a plurality of bumps on a main surface of a semiconductor substrate comprising a measuring device for measuring the electrical characteristics for the semiconductor device. In this aspect of the present invention, electrodes for measuring are disposed at corresponding positions for a plurality of bumps in the measuring device; and a plurality of connecting terminals are disposed for connecting the electrodes for measuring and an external circuit.

In a fixture for measuring electrical characteristics for the semiconductor device according to a fifth aspect of the present invention, at least a part of the electrode for measuring which contacts the bump is flexible and an electrically conductive member.

In a fixture for measuring electrical characteristics for the semiconductor device according to a sixth aspect of the present invention, a coefficient of linear expansion for a main unit of the measuring device is approximately the same as a coefficient of linear expansion for the semiconductor device.

A semiconductor device characteristics measuring apparatus has the fixture for measuring electrical characteristics for the semiconductor device according to the fourth aspect of the present invention.

As explained above, a semiconductor device according to the present invention has a plurality of bumps on a main surface of a semiconductor substrate. By doing this, it is possible to measure various electrical characteristics efficiently by using the bumps. Also, it is possible to reduce cost which is necessary for the characteristics measurement; thus, it is possible to improve the turn-around time (hereinafter called TAT) greatly.

Also, by using the approximately round bumps, processes such as exposure process, etching process, and plating process are not necessary, in contrast to other operations for attaching bumps. In addition, structures for an apparatus for attaching bumps can be simple; therefore, it is possible to reduce cost for producing bumps. Thus, it is possible to reduce cost for producing a semiconductor device.

A fixture for measuring electrical characteristics for the semiconductor device has a measuring device for measuring the electrical characteristics for the semiconductor device which has a plurality of bump on a main surface of a semiconductor substrate. Also, electrodes for measuring are disposed to corresponding positions for a plurality bump in the measuring device, and a plurality of connecting terminal are disposed for connecting the electrodes for measuring and an external circuit. By doing this, it is possible to measure various electrical characteristics in the semiconductor device efficiently; thus, it is possible to reduce costs due to characteristics measurement.

A semiconductor device characteristics measuring apparatus according to the present invention is provided with a fixture for measuring electrical characteristics for the semiconductor device according to the present invention. By doing this, it is possible to measure various electrical characteristics for the semiconductor device which are obtained in various tests such as a wafer Burn-in test, a wafer test, a chip Burn-in test, and a chip test, even if there are various shapes and sizes of semiconductor devices. Thus, it is possible to reduce costs due to the characteristics measurement.

According to structures explained above, it is possible to realize a mounting operation for a semiconductor substrate of small size with high density at low cost and to measure electrical characteristics for a semiconductor wafer and semiconductor chip efficiently in a manufacturing process or after the mounting operation. Also, it is possible to reduce costs due to the characteristics measurement.

### BRIEF DESCRIPTION OF THE DRAWINGS

FIG. 1 is a plan view showing a silicon wafer having bump electrodes according to a first embodiment of the present invention.

FIG. 2 is a cross section view along a line A-A on FIG. 1.

FIG. 3 is a cross section showing a Burn-in socket for a silicon wafer according to a first embodiment of the present invention.

FIG. 4 is a plan view showing a measuring fixture for a Burn-in socket for a silicon wafer according to the first embodiment of the present invention.

FIG. 5 is a cross section showing a measuring plate for a silicon device according to the second embodiment of the present invention.

FIG. 6 is a cross section showing an operation for the measuring plate for a silicon device according to the second embodiment of the present invention.

FIG. 7 is a cross section showing a measuring plate for a silicon device according to the third embodiment of the present invention.

FIG. 8 is a cross section showing an operation for the measuring plate for a silicon device according to the third embodiment of the present invention.

### DETAILED DESCRIPTION OF THE INVENTION

Embodiments for a semiconductor device, a fixture for measuring characteristics for the semiconductor device, and a semiconductor device characteristics measuring apparatus therewith are explained as follows with reference to the drawings.

First Embodiment

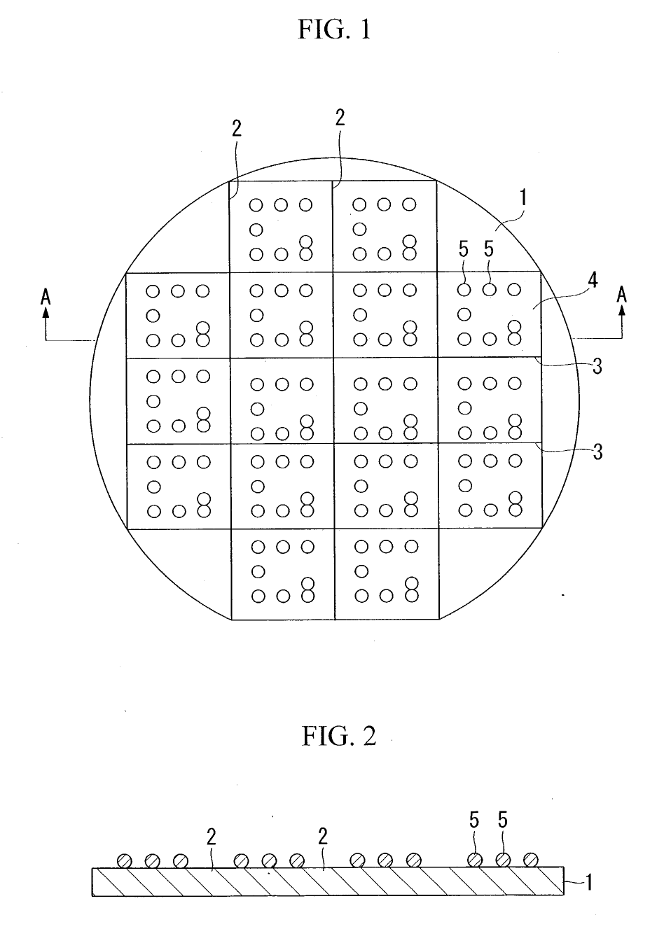

FIG. 1 is a plan view showing a silicon wafer having bump electrodes (semiconductor device) according to a first embodiment of the present invention. FIG. 2 is a cross section view in a line A-A on FIG. 1. In these drawings, reference numeral 1 indicates a silicon wafer. Reference numerals 2 and 3 indicate scribe lines for dividing a surface (a main surface) of the silicon wafer 1 into a plurality of areas. Reference numeral 4 indicates a silicon chip (semiconductor chip) as areas which are divided by the scribe lines 2 and 3. Reference numeral 5 indicates a bump which is formed on a predetermined position on each silicon chip 4.

The bumps 5 are wear-resistant. Also, the bumps 5 are made of electrically conductive members which are durable in repeated use. The shape of the bump 5 can be approximately round or polygonal. The bumps 5 can be preferably made of a gold ball member.

Such a gold ball member is approximately round and made of gold (Au) or a gold alloy. For a gold alloy, an Au—Be gold alloy which contains a certain amount of beryllium (Be), and an Au—Cu gold alloy which contains a certain amount of copper (Cu) are preferably used.

In the silicon wafer 1, it is possible to form bumps 5 on an entire surface of a wafer or on each chip. A method for forming bumps 5 may be selected by taking the factors such as the number of silicon wafers which are processed, the number of chips on the wafers, and numbers of bumps on one chip into account. In particular, in an operation for attaching ball bumps such as gold ball member, processes such as exposure process, etching process, and plating process are not necessary in contrast to other operations for attaching bumps. In addition, structure for an apparatus for attaching bumps can be simple; therefore, it is possible to reduce costs for producing bumps on a silicon wafer. Thus, it is possible to reduce cost for producing a silicon wafer.

Also, it is possible to produce a plurality of silicon chips 4 on a surface (a main surface) of which a plurality of bumps 5 are formed at predetermined positions by performing a dicing operation along scribe lines 2 and 3 by using apparatuses such as a dicing apparatus.

In the silicon chip 4, it is possible to produce bumps at a lower cost, similarly to the case of the silicon wafer 1; thus, it is possible to reduce costs for manufacturing a chip.

The silicon chip 4 can be mounted directly on a printed board by using the bumps 5.

When the silicon chip 4 is mounted on the printed board, the silicon chip 4 is covered and fixed by a resin such as epoxy resin such that the bumps 5 are contacted closely on the printed board.

When the bumps 5 are contacted closely to the printed board, an ultrasonic wave vibration can be further applied to the bumps 5 by using a supersonic wave generating apparatus so as to deposit the bumps 5 on the printed board; thus, contact between the bumps 5 and the printed board increases.

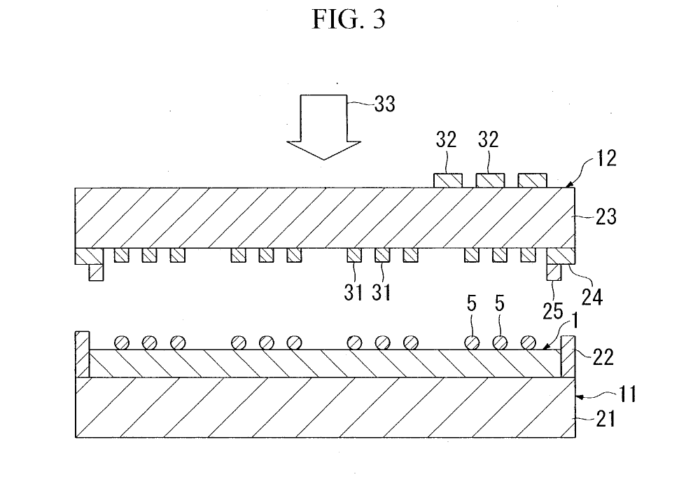

FIG. 3 is a cross section showing a Burn-in socket (characteristics measuring fixture) for a silicon wafer to be used in a Burn-in test (characteristics measurement) apparatus.

The Burn-in socket is provided with a plate 11 for holding a wafer which fixes the silicon wafer 1 and a measuring fixture 12 (measuring device) for measuring an electrical characteristics for the silicon wafer 1.

A main unit for the plate 11 for holding a wafer is made of a member having a coefficient of linear expansion which is approximately the same as a coefficient of linear expansion for the silicon wafer 1. The main unit for the plate 11 for holding a wafer can be a plate 21 of circular plate shape which is made from a silicon, an aluminum nitride, and ceramics such as a silicon carbide. The diameter of the plate 11 for holding a wafer is larger than the diameter of the silicon wafer 1 which is fixed. Around the plate 21, a wafer holding member 22 for fixing the silicon wafer 1 from a peripheral region of the plate 21 is provided.

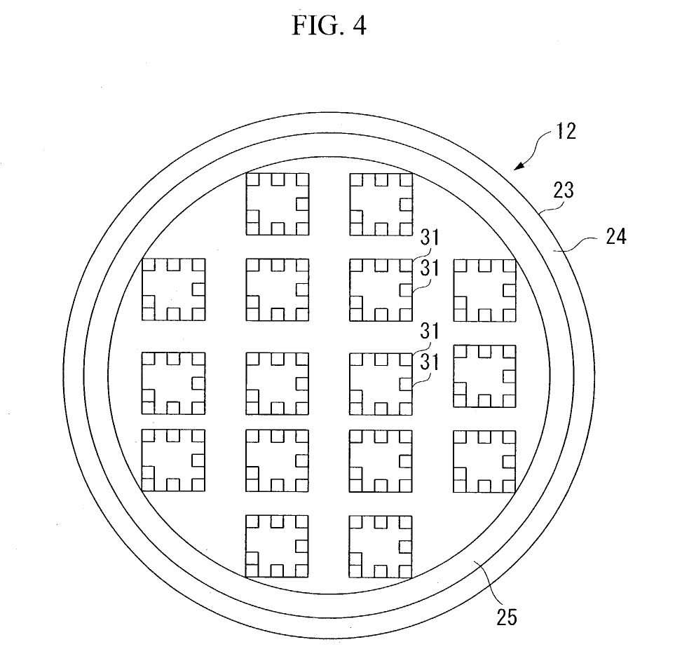

A main unit for the measuring fixture 12 is made of a member having a coefficient of linear expansion which is approximately the same as a coefficient of linear expansion for the silicon wafer 1 such as a silicon, an aluminum nitride, and a ceramics such as silicon carbide. As shown in FIGS. 3 and 4, the main unit for the measuring fixture 12 can be a plate 23 having a circular plate shape. On the outermost region on a surface of the plate 23, which faces the plate 11 for holding a wafer, a ring plate guide 24 for holding a wafer which guides and fits with the wafer holding member 22 is disposed. A ring 25 which is formed on an inner surface of the ring plate guide 24 fits the wafer holding member 22.

Measuring pads 31 (measuring electrodes) for measuring electrical characteristics for the silicon wafer 1 are disposed on positions corresponding to a plurality of bumps 5 which are disposed on the silicon wafer 1 which is fixed on a surface (bottom surface) of the plate 23 which faces the plate 11 for holding a wafer. Various wirings for components such as a power supply, a clock, an input signal, and a monitor terminal are bonded to these measuring pads 31. The silicon wafer 1 is connected to an external circuit via the connecting terminals 32 which are disposed on the plate 23.

At least a part of the measuring pads 31 which contact the bump 5 is flexible and is made of an electrically conductive member such as a conductive rubber.

A Burn-in test apparatus to which a Burn-in socket is employed has a chamber to which a plurality of Burn-in sockets can be attached. In the Burn-in test apparatus, it is possible to pick up a monitor signal which can be obtained from each chip 4 on the fixed silicon wafer 1 by supplying a predetermined voltage and current preferably to each Burn-in socket.

Next, a Burn-in test is performed to the silicon wafer 1 by using the Burn-in socket and the Burn-in test apparatus. First, the silicon wafer 1 is put on the plate 21 on the plate 11 for holding a wafer such that the bumps 5 faces upward. Consequently, the silicon wafer 1 is fixed on the plate 21 by using the wafer holding member 22.

Next, the plate 11 for holding a wafer and the measuring fixture 12 are disposed so as to face each other, and the position of the measuring fixture 12 is adjusted by a imagines apparatus such that the positions of the bumps 5 on the silicon wafer 1 and the positions of the measuring pads 31 on the measuring fixture 12 correspond to each other. Consequently, the plate guide 24 for holding a wafer on the measuring fixture 12 is fit to the wafer holding member 22 on the plate 11 for holding a wafer so as to fix the plate guide 24 by pressing the plate 23 in a direction 33 shown in FIG. 3.

By doing this, the measuring pads 31 on the measuring fixture 12 are connected electrically to the bumps 5 on the silicon wafer 1 under compressed condition by its resilience.

After that, the Burn-in socket is set in the chamber in the Burn-in test apparatus manually or automatically. An acceleration test is performed under conditions such that the inside of the chamber is heated to a predetermined temperature.

Here, various signals which are output from each chip 4 on the silicon wafer 1 are picked up by the measuring apparatus which is disposed outside the chamber via the measuring pads 31 and the connecting terminals 32.

Also, in order to perform a wafer test for the silicon wafer 1 by using the Burn-in socket, first, a measuring probe which is made of a metal such as a Tungsten (W) member is contacted to a predetermined bump 5 on the silicon wafer 1 which is fixed on the plate 21 as explained above. After an electrical connection between the bump 5 and the measuring probe is established, various measurements are performed in the wafer test.

Conventionally, in the wafer test, measurements have been performed such that the measuring probe is contacted to a plain electrode such as an aluminum pad which is formed on the wafer. In such a case, there was a problem in that a defective connection tends to occur due to generation of aluminum oxides. In contrast, in the present invention, there is no possibility that defective connection will occur due to generation of aluminum oxide by using an approximately round bump or a polygonal bump for the bump 5. More preferably, a gold ball member should be used for the bump 5.

It is possible to perform various tests such as a Burn-in test for the silicon chip 4 and chip test by transforming the Burn-in socket so as to fit for the use of a silicon chip.

In this case, from an efficiency point of view, it is a preferable method that the chip 4 be dropped from above so as to correspond to the positions of the pad 31 of the Burn-in socket for the silicon chip and the chip 4 is fixed to the Burn-in socket.

As explained above in detail, in the silicon wafer 1 according to the first embodiment of the present invention, the approximately round bumps 5 or polygonal bumps 5 made of a gold ball member are provided. Therefore, it is possible to measure various electrical characteristics efficiently by using the bump 5. Thus, it is possible to reduce cost for characteristics measurement; therefore, it is possible to greatly improve the TAT. Here, TAT is an index for evaluating an efficiency in measuring electrical characteristics for the semiconductor device in the semiconductor industry.

Also, processes such as exposure process, etching process, and plating process are not necessary in contrast to other operations for attaching bumps. In addition, structures for an apparatus for attaching bumps can be simple; therefore, it is possible to reduce costs for producing bumps on a silicon wafer. Thus, it is possible to reduce costs for producing silicon wafers.

In the Burn-in socket according to the present embodiment of the present invention, the plate 11 for holding a wafer and the measuring fixture 12 are provided. Also, the measuring pads 31 for measuring electrical characteristics of the silicon wafer 1 is disposed on the plate 23 on the measuring fixture 12. By doing this, it is possible to perform various tests by using the bumps 5 efficiently; thus, it is possible to reduce costs which are necessary for the tests.

The silicon chip 4 according to the present embodiment of the present invention is mounted to a printed board directly, and it is possible to maintain height of members which are mounted on the printed board; therefore, it is possible to realize higher density mounting operation.

Also, the silicon chip 4 itself is mounted on the printed board; thus, the final package is produced under conditions that the bumps 5 are formed on the chip 4. Therefore, a resin mold is not necessary; thus, it is possible to reduce costs which are necessary for the mold resin.

Also, conventionally, post-molding-tests such as the Burn-in test and the chip test were performed after the wafer test. According to the present invention, it is possible to omit such tests; thus, it is possible to greatly reduce costs for such various tests.

Second Embodiment

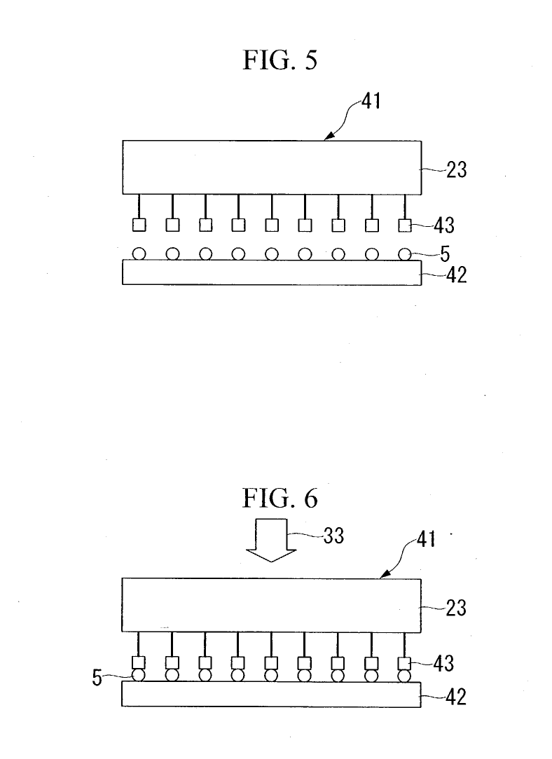

FIG. 5 is a cross section showing a measuring plate (characteristics measuring fixture) for a silicon device which is used in the bump test (characteristics measurement) for the silicon device according to the second embodiment of the present invention.

A main unit for the measuring plate 41 is a plate 23 having a circular plate shape similarly to the case for the measuring fixture 12 according to the first embodiment which is explained above. Extensible electrodes 43 (measuring electrodes) for measuring electrical characteristics for the silicon device 42 are attached on a bottom surface of the plate 23 which faces the silicon device 42.

In order to perform the bump test (characteristics measurement) for the silicon device by using the measurement plate 41, as shown in FIG. 6, first, the measuring plate 41 and the silicon device 42 are faced to each other. After that, the position of the measuring plate 41 is adjusted such that the position of the bumps 5 on the silicon device 42 are synchronized to the positions of the extensible electrode 43 on the measuring plate 41. Furthermore, the extensible electrodes 43 on the measuring plate 41 are compressed to the bumps 5 on the silicon device 42 in a direction 33 shown in the drawing from above so as to fix the extensible electrodes 43.

By doing this, the extensible electrodes 43 on the measuring plate 41 are connected electrically to the bumps 5 on the silicon device 42 under compressed condition by its resilience.

According to the present embodiment of the present invention, the extensible electrodes 43 on the measuring plate 41 is fixed on the bumps 5 on the silicon device 42 by compressing in a direction 33 from above. Therefore, it is possible to perform various tests by using the extensible electrodes 43 efficiently; thus, it is possible to reduce cost which is necessary for various tests.

Third Embodiment

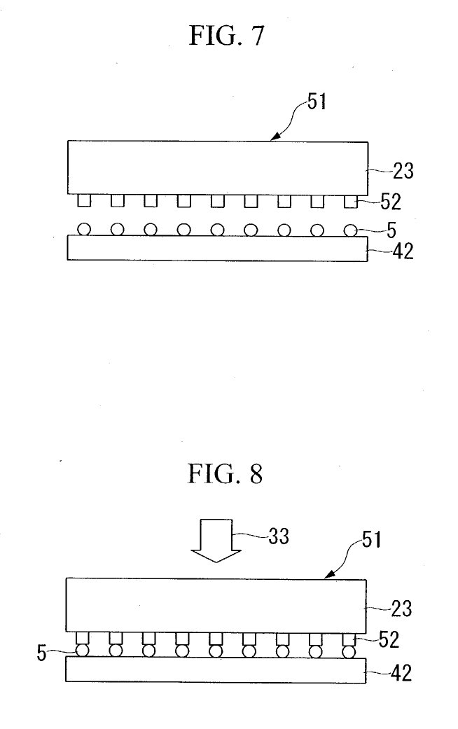

FIG. 7 is a cross section showing a measuring plate (characteristics measuring fixture) for a silicon device which is used in the bump test (characteristics measurement) for the silicon device according to a third embodiment of the present invention.

A main unit for the measuring plate 51 is a plate 23 having a circular plate shape similarly to the case for the measuring plate 41 according to the second embodiment which is explained above. Electrodes 52 for measuring electrical characteristics for the silicon device 42 are attached on a bottom surface of the plate 23 which faces the silicon device 42.

In order to perform the bump test (characteristics measurement) for the silicon device by using the measurement plate 51, as shown in FIG. 8, first, the measuring plate 51 and the silicon device 42 are faced to each other. After that, the position of the measuring plate 51 is adjusted such that the position of the bumps 5 on the silicon device 42 are synchronized to the positions of the electrode 52 on the measuring plate 51. Furthermore, the electrodes 52 on the measuring plate 51 are compressed to the bumps 5 on the silicon device 42 in a direction 33 shown in the drawing from above so as to fix the electrodes 52.

By doing this, the electrodes 52 on the measuring plate 51 are connected electrically to the bumps 5 on the silicon device 42 under compressed condition by its resilience.

According to the present embodiment of the present invention, the electrodes 52 on the measuring plate 51 is fixed on the bumps 5 on the silicon device 42 by compressing in a direction 33 from above. Therefore, it is possible to perform various tests by using the electrodes 52 efficiently; thus, it is possible to reduce costs necessary for various tests.

What is claimed is:

1. A semiconductor device having a plurality of bumps on a main surface of a semiconductor substrate.

2. A semiconductor device according to claim 1 wherein the bumps are electrically conductive wear-resistant members.

3. A semiconductor device according to claim 1 or 2 wherein the bumps are approximately round or polygonal.

4. A fixture for measuring electrical characteristics for the semiconductor device having a plurality of bumps on a main surface of a semiconductor substrate comprising a measuring device for measuring the electrical characteristics for the semiconductor device, wherein
electrodes for measuring are disposed to corresponding positions for a plurality of bumps in the measuring device; and
a plurality of connecting terminal are disposed for connecting the electrodes for measuring and an external circuit.

5. A fixture for measuring electrical characteristics for the semiconductor device according to claim 4 wherein at least a part of the electrode for measuring which contacts a bump is flexible and an electrically conductive member.

6. A fixture for measuring electrical characteristics for the semiconductor device according to claim 4 wherein a coefficient of linear expansion for a main unit of the measuring device is approximately the same as a coefficient of linear expansion for the semiconductor device.

7. A semiconductor device characteristics measuring apparatus having the fixture for measuring electrical characteristics for the semiconductor device according to claim 4.
